(19) United States
(12) Patent Application Publication
(10) Pub. No.: US 2026/0334114 A1
(43) Pub. Date: Oct. 22, 2026

(54) METHOD OF MANUFACTURING SEMICONDUCTOR DEVICE

(71) Applicant: RENESAS ELECTRONICS CORPORATION, Tokyo (JP)

(72) Inventor: Masakazu NAKANO, Tokyo (JP)

(21) Appl. No.: 19/530,564

(22) Filed: Feb. 5, 2026

(30) Foreign Application Priority Data
Mar. 27, 2025 (JP) 2025-053464

(51) Int. Cl. H10P 30/22; H10D 1/00; H10D 30/01; H10D 64/27; H10D 64/66; H10P 50/00; H10W 10/00; H10D 1/47; H10D 1/68; H10D 30/65; H10W 10/17

(52) U.S. Cl. CPC H10P 30/22; H10D 1/021; H10D 1/041; H10D 30/0281; H10D 64/518; H10D 64/661; H10P 50/71; H10W 10/0147; H10D 1/47; H10D 1/692; H10D 30/65; H10W 10/17

(57) ABSTRACT

A gate oxide film, a first polysilicon film, and a silicon nitride film are sequentially formed on a first main surface, which includes an isolation region defined in a semiconductor substrate. An implant species that promotes oxidation is implanted into the semiconductor substrate located in the isolation region. A trench is formed in the isolation region. An oxidation process is performed in the trench. An isolation insulating film is formed in the trench. After forming a second polysilicon film in a manner that contacts an upper surface of the first polysilicon film and a surface of the isolation insulating film, a gate electrode is formed by patterning.

### CROSS-REFERENCE TO RELATED APPLICATIONS

The disclosure of Japanese Patent Application No. 2025-053464 filed on Mar. 27, 2025, including the specification, drawings and abstract is incorporated herein by reference in its entirety.

### BACKGROUND

The present invention relates to a method of manufacturing a semiconductor device, which can be suitably used for manufacturing a semiconductor device having an LDMOS (Laterally Diffused Metal Oxide Semiconductor) transistor, for example.

There are disclosed techniques listed below.

[Patent Document 1] Japanese Unexamined Patent Application Publication No. 2020-136527

Conventionally, there is a semiconductor device having an LDMOS transistor that requires high breakdown voltage (Patent Document 1). The LDMOS transistor has a source region, a drain region, and a gate electrode, and is formed at one main surface of a semiconductor substrate. The source region and the drain region are formed with a space between the source region and the drain region. The gate electrode is formed on a region of the semiconductor substrate located between the source region and the drain region, via a gate insulating film.

In addition, an isolation insulating film is formed between the source region and the drain region. The isolation insulating film is formed in a trench. The gate electrode is formed on the semiconductor substrate located between the isolation insulating film and the source region, and on the isolation insulating film. The gate electrode is formed as follows.

A part of the polysilicon film, which becomes the gate electrode, is formed on the upper surface of the semiconductor substrate via a gate insulating film. Next, a silicon nitride film is formed on the polysilicon film so as to cover the polysilicon film. Next, the silicon nitride film is patterned, and the semiconductor substrate is etched using the patterned silicon nitride film as an etching mask, thereby forming a trench in the semiconductor substrate. An isolation insulating film is formed in the trench. Next, after the silicon nitride film is removed, the remaining polysilicon film, which becomes the gate electrode, is formed. Thereafter, the gate electrode is formed by patterning the polysilicon film and the like.

### SUMMARY

In the above-described semiconductor device, it is assumed that foreign matter may occur in forming the gate electrode, for example, when forming the gate insulating film or when forming a part of the polysilicon film.

If a trench is formed in a state where foreign matter has occurred at the portion of the gate insulating film or the portion of the polysilicon film located in the region where the trench is formed, the foreign matter acts as a mask, and the portion of the semiconductor substrate (silicon) is not removed, and there is a risk that silicon will occur as needle-like residues in the trench.

In such a case, after the isolation insulating film is formed in the trench, the tip portion of the needle-like residue is close to the polysilicon film in a state where the gate electrode made of a polysilicon film is formed on the isolation insulating film, and there is a risk that the gate electrode (polysilicon) and the semiconductor substrate (silicon) may be electrically short-circuited.

Therefore, even if needle-like residues occur in the trench, there is a demand for a method of manufacturing a semiconductor device that can suppress electrical short-circuiting between the polysilicon pattern such as the gate electrode and the needle-like residues.

Other objects and novel features will become apparent from the description of this specification and the accompanying drawings.

A method of manufacturing a semiconductor device according to one embodiment includes the following steps. A semiconductor substrate having a first main surface is prepared. A first polysilicon film is formed on the first main surface via a first insulating film. A first mask material is formed on the first polysilicon film. A first etching process is performed on the first polysilicon film, on the first insulating film, and on the semiconductor substrate using the first mask material as an etching mask to form an isolation trench in a part of the semiconductor substrate. An oxidation process is performed in the isolation trench. An isolation insulating film is formed in the isolation trench. A second polysilicon film is formed on the upper surface of the first polysilicon film and on the upper surface of the isolation insulating film. By performing a second etching process on the second polysilicon film and on the first polysilicon film, a polysilicon pattern extending from the first main surface onto the isolation insulating film is formed. Before performing an oxidation process in the isolation trench, an implant species is implanted into a part of the semiconductor substrate by ion implantation.

According to the method of manufacturing a semiconductor device according to one embodiment, it is possible to suppress electrical short-circuiting between the needle-like residues and the polysilicon pattern.

### BRIEF DESCRIPTION OF THE DRAWINGS

FIG. 1 is a cross-sectional view showing an example of a semiconductor device manufactured by a method of manufacturing a semiconductor device according to a first embodiment.

FIG. 2 is a cross-sectional view showing a step of the method of manufacturing a semiconductor device shown in FIG. 1 in the first embodiment.

FIG. 3 is a cross-sectional view showing a step performed after the step shown in FIG. 2 in the first embodiment.

FIG. 4 is a cross-sectional view showing a step performed after the step shown in FIG. 3 in the first embodiment.

FIG. 5 is a partially enlarged cross-sectional view showing a step performed after the step shown in FIG. 4 in the first embodiment.

FIG. 6 is a partially enlarged cross-sectional view showing a step performed after the step shown in FIG. 5 in the first embodiment.

FIG. 7 is a partially enlarged cross-sectional view showing a step performed after the step shown in FIG. 6 in the first embodiment.

FIG. 8 is a partially enlarged cross-sectional view showing a step performed after the step shown in FIG. 7 in the first embodiment.

FIG. 9 is a partially enlarged cross-sectional view showing a step performed after the step shown in FIG. 8 in the first embodiment.

FIG. 10 is a partially enlarged cross-sectional view showing a step performed after the step shown in FIG. 9 in the first embodiment.

FIG. 11 is a partially enlarged cross-sectional view showing a step performed after the step shown in FIG. 10 in the first embodiment.

FIG. 12 is a partially enlarged cross-sectional view showing a step performed after the step shown in FIG. 11 in the first embodiment.

FIG. 13 is a partially enlarged cross-sectional view showing a step performed after the step shown in FIG. 12 in the first embodiment.

FIG. 14 is a partially enlarged cross-sectional view showing a step performed after the step shown in FIG. 13 in the first embodiment.

FIG. 15 is a cross-sectional view showing a step performed after the step shown in FIG. 14 in the first embodiment.

FIG. 16 is a cross-sectional view showing a step performed after the step shown in FIG. 15 in the first embodiment.

FIG. 17 is a partially enlarged cross-sectional view showing a step of the method of manufacturing a semiconductor device according to a comparative example.

FIG. 18 is a partially enlarged cross-sectional view showing a step performed after the step shown in FIG. 17.

FIG. 19 is a partially enlarged cross-sectional view showing a step performed after the step shown in FIG. 18.

FIG. 20 is a partially enlarged cross-sectional view showing a step performed after the step shown in FIG. 19.

FIG. 21 is a partially enlarged cross-sectional view showing a step performed after the step shown in FIG. 20.

FIG. 22 is a diagram showing the structure of needle-like residues in the first embodiment and the structure of needle-like residues in the comparative example.

FIG. 23 is a partially enlarged cross-sectional view showing a region where an implant species that promotes oxidation is implanted in the first embodiment.

FIG. 24 is a diagram for explaining the effect of implanting an implant species that promotes oxidation in the first embodiment.

FIG. 25 is a diagram showing the evaluation results of a simulation of an implant species that promotes oxidation in the first embodiment.

FIG. 26 is a partially enlarged cross-sectional view showing a step of the method of manufacturing a semiconductor device according to a second embodiment.

FIG. 27 is a partially enlarged cross-sectional view showing a step performed after the step shown in FIG. 26 in the second embodiment.

FIG. 28 is a partially enlarged cross-sectional view showing a step performed after the step shown in FIG. 27 in the second embodiment.

FIG. 29 is a partially enlarged cross-sectional view showing a step performed after the step shown in FIG. 28 in the

second embodiment.

FIG. 30 is a partially enlarged cross-sectional view showing a step performed after the step shown in FIG. 29 in the second embodiment.

FIG. 31 is a diagram showing the evaluation results of a simulation of an implant species that promotes oxidation in the second embodiment.

FIG. 32 is a partially enlarged cross-sectional view showing a modified example of the polysilicon pattern in each embodiment.

FIG. 33 is a partially enlarged perspective view showing the shape of needle-like residues in each embodiment.

FIG. 34 is a partially enlarged cross-sectional view along the section line XXXIV-XXXIV shown in FIG. 33 in each embodiment.

### DETAILED DESCRIPTION

### First Embodiment

As an example of the method of manufacturing a semiconductor device according to the first embodiment, a semiconductor device including an LDMOS transistor will be described.

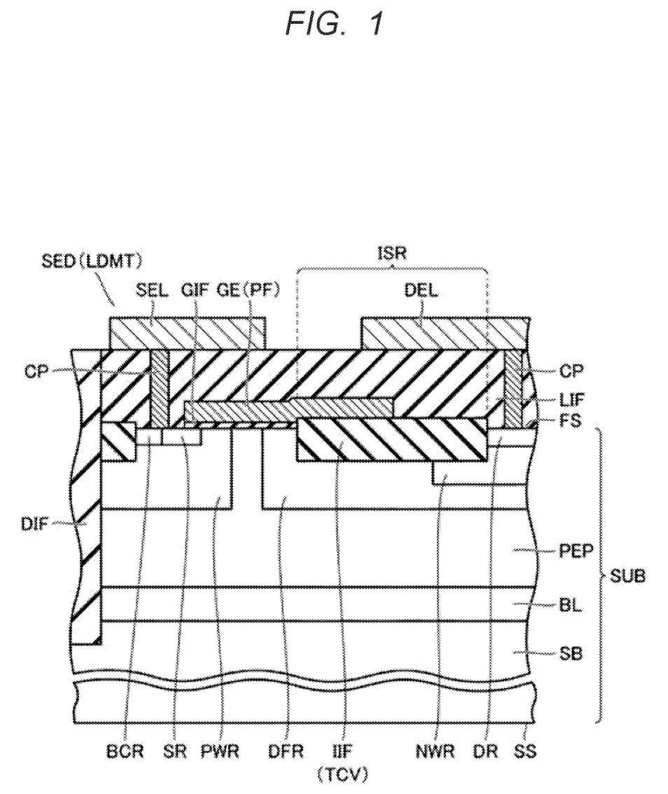

As shown in FIG. 1, a semiconductor substrate SUB has a first main surface FS and a second main surface SS located on the opposite side of the first main surface FS. In the semiconductor device SED, an LDMOS transistor LDMT is formed at the first main surface FS of the semiconductor substrate SUB. The LDMOS transistor LDMT includes a source region SR, a drain region DR, a gate insulating film GIF (first insulating film), a gate electrode GE (polysilicon pattern), a body region PWR, and a drift region DFR.

The semiconductor substrate SUB includes a p-type substrate SB, an n-type buried region BL, and a p-type epitaxial region PEP. The epitaxial region PEP is located on the p-type substrate SB. The buried region BL is interposed between the p-type substrate SB and the epitaxial region PEP.

The source region SR, the drain region DR, the body region PWR, and the drift region DFR are formed in the epitaxial region PEP. The body region PWR and the drift region DFR are formed from the upper surface (first main surface FS) of the epitaxial region PEP to a predetermined depth, respectively. The body region PWR is separated from the drift region DFR.

The drain region DR is formed from the upper surface (first main surface FS) of the drift region DFR to a position shallower than the bottom of the drift region DFR. In addition, an n-type well NWR is formed in the drift region DFR from the bottom of the drain region DR to a position shallower than the bottom of the drift region DFR.

Furthermore, an isolation insulating film IIF is formed in the drift region DFR. The isolation insulating film IIF is located between the drain region DR and the source region SR. An isolation region ISR is defined at the first main surface FS of the semiconductor substrate SUB. In the isolation region ISR, a trench TCV (isolation groove) is formed, which is deeper than the bottom of the drain region DR and shallower than the bottom of the drift region DFR from the first main surface FS of the semiconductor substrate SUB. The isolation insulating film IIF is formed in the trench TCV. The trench TCV is formed in a part of the semiconductor substrate SUB. More specifically, the trench TCV is formed in the drift region DFR.

The source region SR is formed from the upper surface (first main surface FS) of the body region PWR to a position shallower than the bottom of the body region PWR. Also, in the body region PWR, a p-type body contact region BCR is formed. The body contact region BCR is formed from the upper surface (first main surface FS) of the body region PWR to a position shallower than the bottom of the body region PWR.

The gate insulating film GIF is formed on the first main surface FS of the portion of the semiconductor substrate SUB (epitaxial region PEP, body region PWR, drift region DFR) located between the source region SR and the isolation insulating film IIF. The gate electrode GE is formed to be in contact with the gate insulating film GIF. The gate electrode GE is formed to extend from the first main surface FS over the isolation insulating film IIF towards the drain region DR, in a manner that it contacts the isolation insulating film IIF.

An interlayer insulating film LIF is formed on the first main surface FS of the semiconductor substrate SUB to cover the gate electrode GE and others. Contact plugs PG electrically connected to the drain region DR and contact plugs PG electrically connected to the source region SR are formed to penetrate through the interlayer insulating film LIF.

The drain electrode DEL and the source electrode SEL are formed to be in contact with the interlayer insulating film LIF. The drain electrode DEL is electrically connected to the contact plug PG, which is electrically connected to the drain region DR. The source electrode SEL is electrically connected to the contact plug PG, which is electrically connected to the source region SR. Additionally, an isolation insulating film DIF is formed to penetrate through the interlayer insulating film LIF and the epitaxial region PEP, reaching the p-type substrate SB. The semiconductor device SED equipped with an LDMOS transistor LDMT is configured as described above.

In the aforementioned semiconductor device SED, even if needle-like residues occur during the formation of the trench TCV, it is possible to suppress the occurrence of electrical short circuits between the gate electrode GE and the semiconductor substrate SUB (drift region DFR). Next, an example of the manufacturing method of the semiconductor device SED will be described.

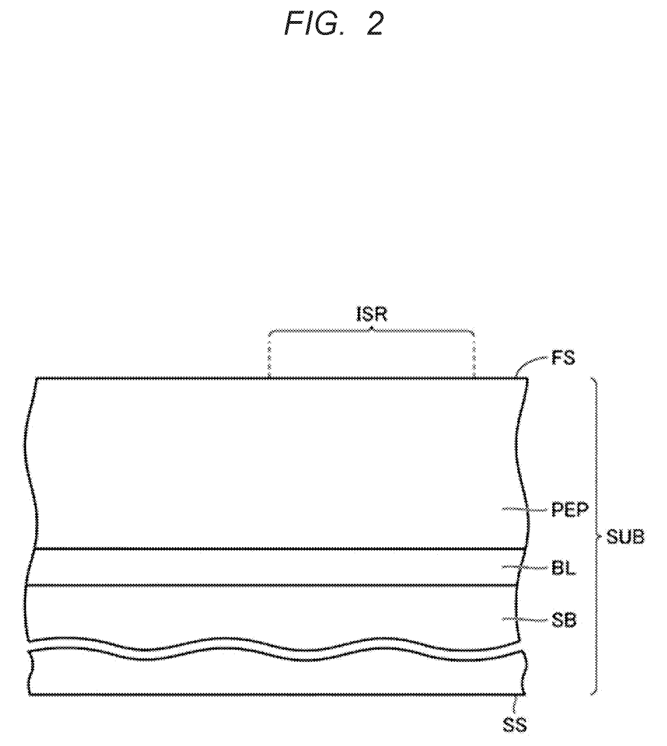

As shown in FIG. 2, a semiconductor substrate SUB is prepared. After implanting n-type impurities into the upper surface of the p-type substrate SB, a p-type epitaxial region PEP is formed on the p-type substrate SB by the epitaxial method. The n-type impurities implanted into the p-type substrate SB form an n-type buried region BL between the p-type substrate SB and the epitaxial region PEP. An isolation region ISR is defined at the first main surface FS of the semiconductor substrate SUB.

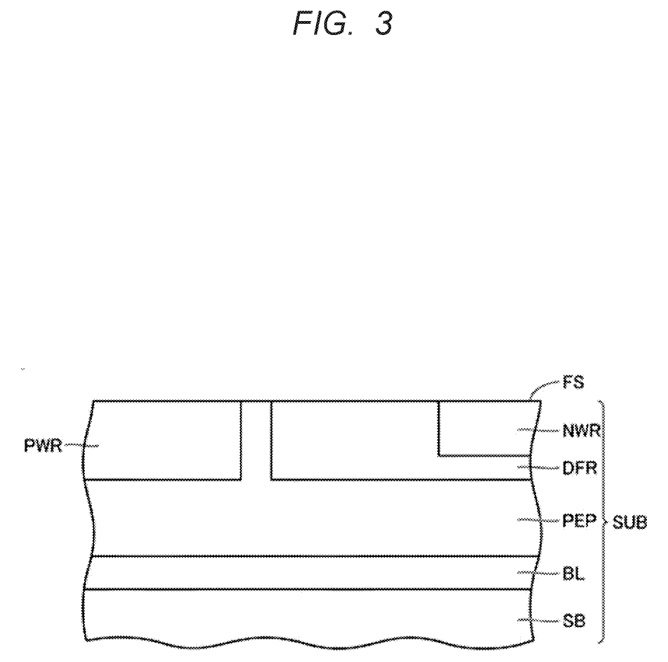

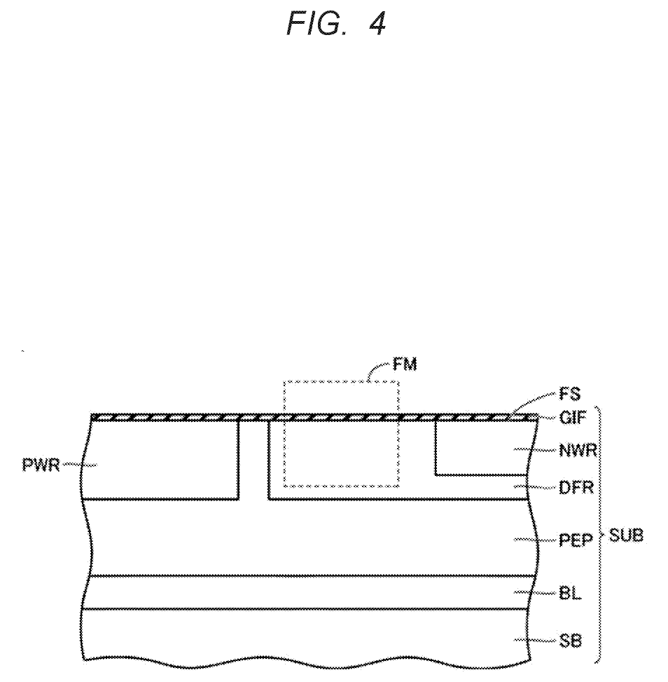

Next, as shown in FIG. 3, a predetermined photolithography process is performed on the first main surface FS of the semiconductor substrate SUB, and p-type impurities are implanted to form the body region PWR. A predetermined photolithography process is performed on the first main surface FS of the semiconductor substrate SUB, and n-type impurities are implanted to form the n-type drift region DFR. A predetermined photolithography process is performed on the first main surface FS of the semiconductor substrate SUB, and n-type impurities are implanted to form the n-type well NWR. Next, as shown in FIG. 4, a thermal oxidation process is performed on the semiconductor substrate SUB to form the gate insulating film GIF on the first main surface FS.

Next, the isolation insulating film IIF and the gate electrode GE are formed. From here, to explain the process in more detail, the area in the dotted frame FM shown in FIG. 4 will be enlarged and explained.

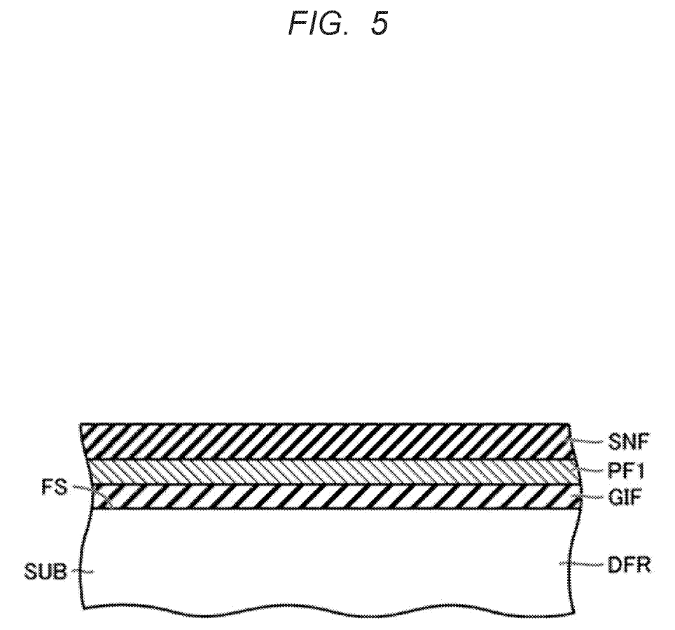

As shown in FIG. 5, for example, by chemical vapor deposition, the first polysilicon film PF1 is formed to be in contact with the upper surface of the gate insulating film GIF. The first polysilicon film PF1 becomes a part of the gate electrode GE. Next, for example, by chemical vapor deposition, a silicon nitride film SNF is formed to be in contact with the first polysilicon film PF1. The silicon nitride film SNF functions as a hard mask (first mask material) when forming the trench TCV, as will be described later.

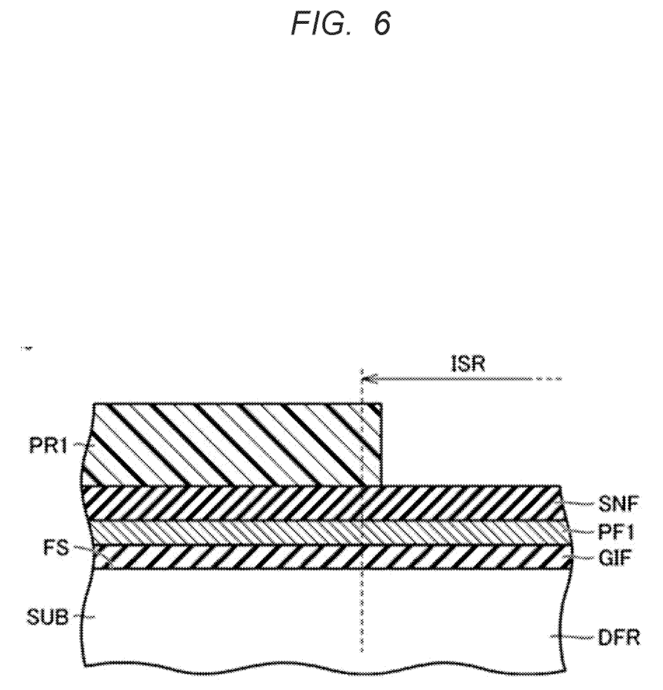

Next, as shown in FIG. 6, by performing a predetermined photolithography process, a photoresist pattern PR1 (second mask material) is formed to be in contact with the upper surface of the silicon nitride film SNF. At this time, the photoresist pattern PR1 is formed in a manner that a part of the photoresist pattern PR1 overlaps the region where the trench TCV is to be formed.

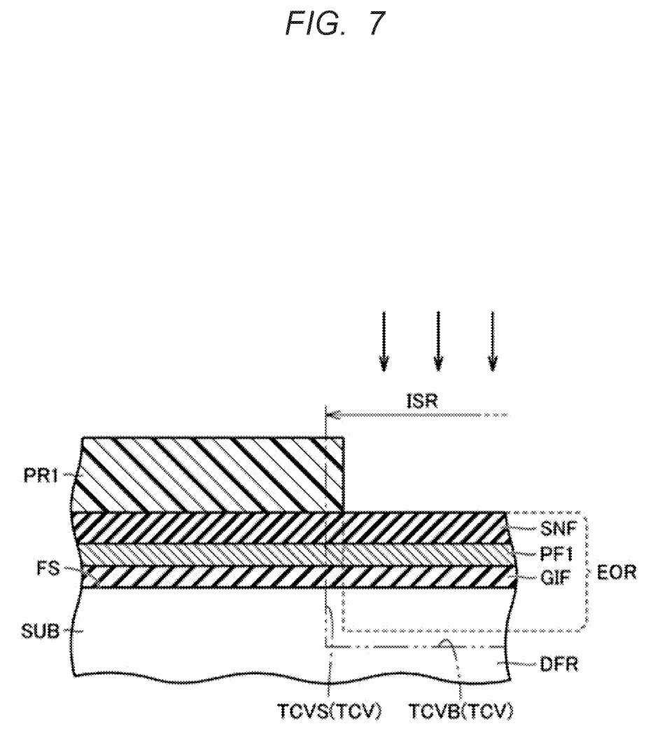

Next, as shown in FIG. 7, using the photoresist pattern PR1 as an implantation mask, for example, phosphorus is implanted by ion implantation. Phosphorus is implanted as an implant species to promote oxidation. At this time, phosphorus is implanted as an implantation region EOR, from the upper surface of the silicon nitride film SNF through the upper surface of the semiconductor substrate SUB, to a region shallower than the bottom of the trench TCV to be formed in a later step.

More specifically, phosphorus as an implant species is implanted into the portion of the semiconductor substrate SUB that is shallower than the position that becomes the bottom surface TCVB of the trench TCV and more inward than the position that becomes the sidewall surface TCVS of the trench TCV. The implantation energy of phosphorus is, for example, 100 keV or more and 110 keV or less. The dose amount of phosphorus is, for example, 1.0×10¹⁵ cm⁻² or more and 5×10¹⁵ cm⁻² or less. These implantation conditions will be explained later. Thereafter, the photoresist pattern PR1 is removed.

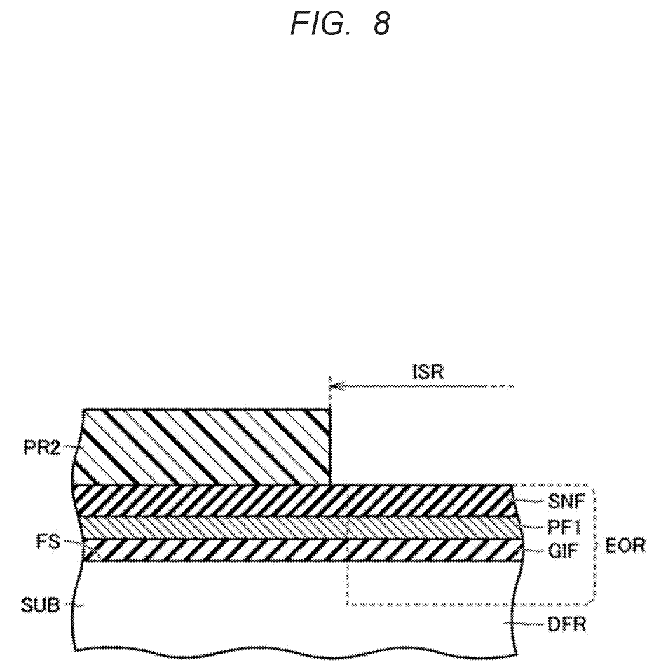

Next, as shown in FIG. 8, by performing a predetermined photolithography process, a photoresist pattern PR2 is formed to be in contact with the upper surface of the silicon nitride film SNF. The photoresist pattern PR2 is formed to expose the silicon nitride film SNF located in the isolation region ISR defined at the first main surface FS.

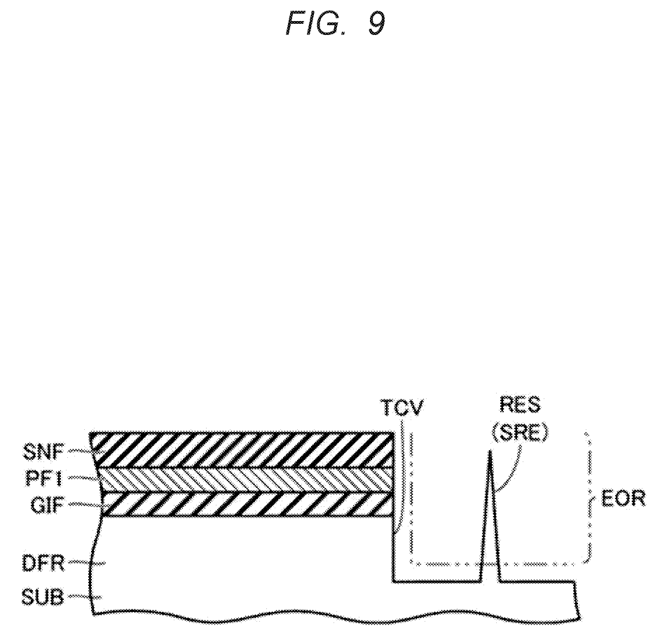

Next, using the photoresist pattern PR2 as an etching mask, a hard mask is formed by etching the silicon nitride film SNF. Furthermore, using the hard mask as an etching mask, etching is performed on the first polysilicon film PF1 and the semiconductor substrate SUB. As a result, as shown in FIG. 9, a trench TCV (isolation groove) is formed. At this time, the trench TCV is formed deeper than the implantation region EOR. Also, if foreign matter has occurred in the first polysilicon film PF1 or the silicon nitride film SNF, etc., the foreign matter may act as a mask, and needle-like residues RES may occur in the trench TCV.

The needle-like residues RES include silicon SRE located in the drift region DFR. In the needle-like residues RES, there are parts where phosphorus has been implanted and parts where phosphorus has not been implanted. Phosphorus is implanted into a portion of the needle-like residues RES located over the two-dot chain line where the implantation region EOR is located. Phosphorus is not implanted into a portion of the needle-like residues RES located under the two-dot chain line.

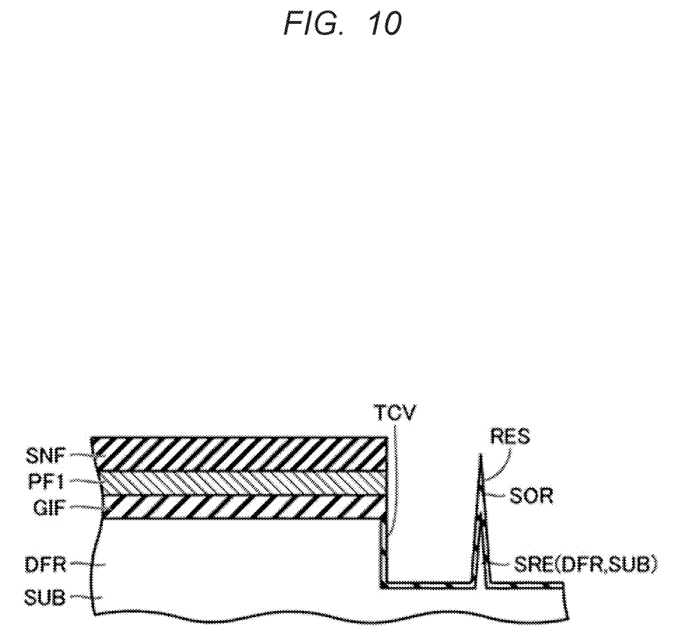

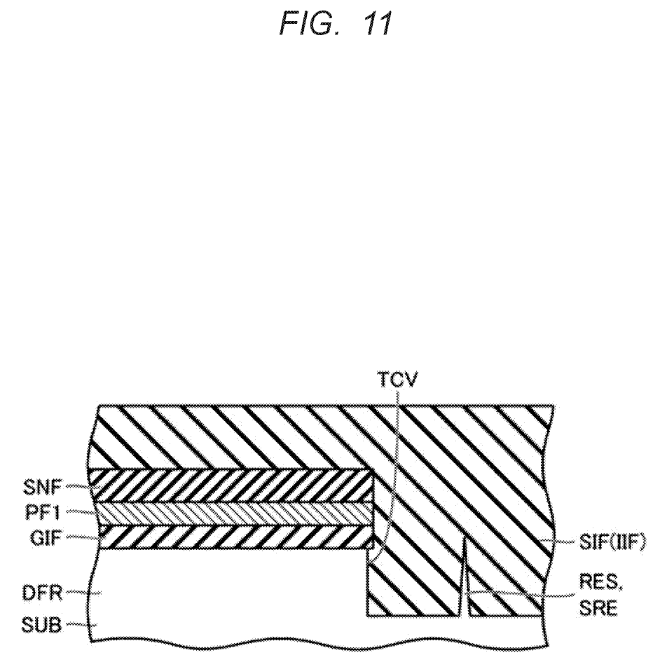

Next, as shown in FIG. 10, by performing a thermal oxidation process (liner oxidation), a silicon oxide film SOR is formed on the bottom surface and sidewall surface of the exposed trench TCV. Also, if needle-like residues RES have occurred, a silicon oxide film SOR is formed on the surface of the needle-like residues RES (silicon SRE, etc.). Next, as shown in FIG. 11, for example, by chemical vapor deposition, a silicon oxide film SIF is formed to cover the silicon nitride film SNF, etc., in a manner that fills the trench TCV.

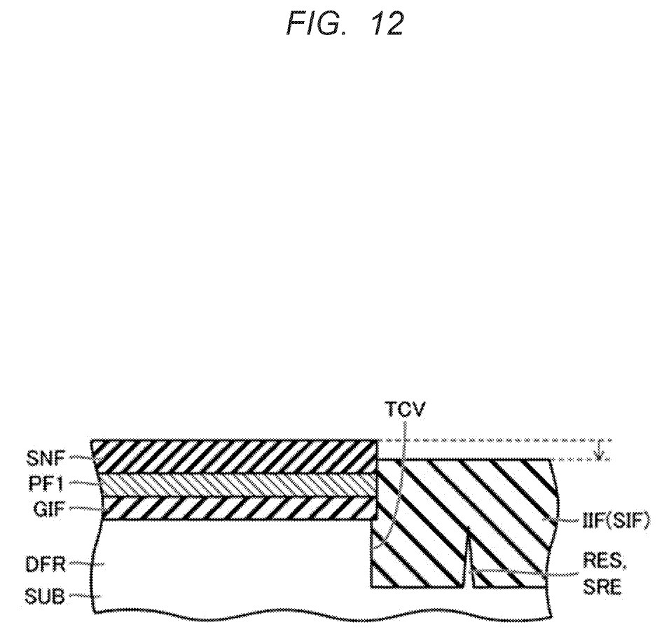

Next, as shown in FIG. 12, by performing chemical mechanical polishing on the silicon oxide film SIF, the portion of the silicon oxide film SIF located on the upper surface of the silicon nitride film SNF is removed. Furthermore, by performing etching on the silicon oxide film SIF, the isolation insulating film IIF is formed. By this etching process, the position of the upper surface of the isolation insulating film IIF becomes lower than the position of the upper surface of the silicon nitride film SNF (see downward arrow). This is to reduce the step formed between the first polysilicon film PF1 and the isolation insulating film IIF.

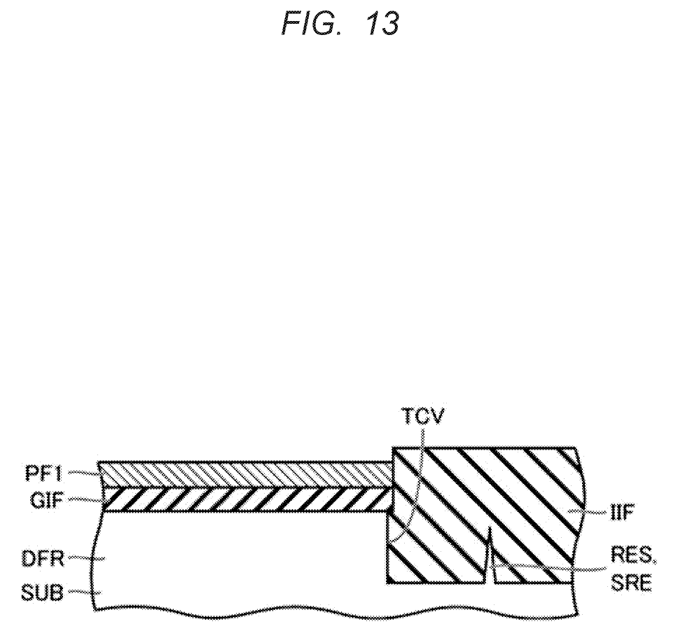

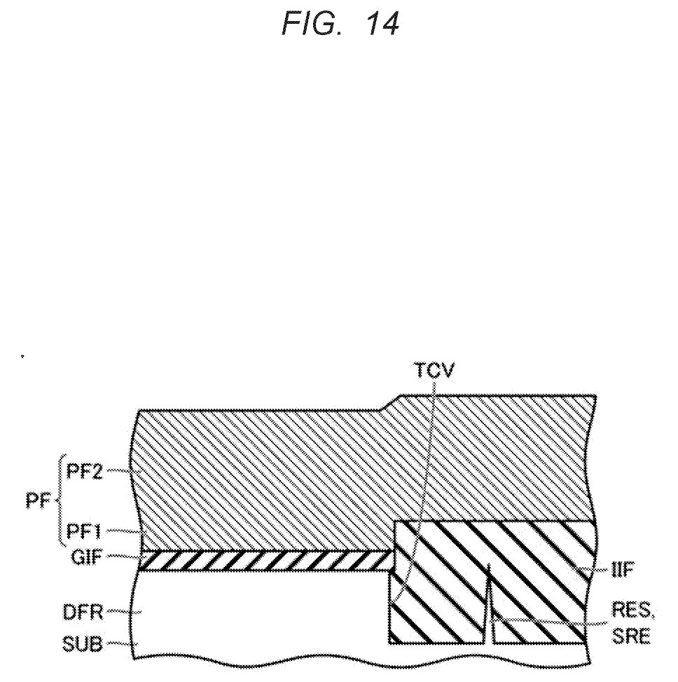

Next, as shown in FIG. 13, by performing etching on the silicon nitride film SNF, the silicon nitride film SNF is removed. Next, as shown in FIG. 14, for example, by chemical vapor deposition, a second polysilicon film PF2 is formed to be in contact with the first polysilicon film PF1. The second polysilicon film PF2 becomes a part of the gate electrode GE. Next, by performing a predetermined photolithography process, a photoresist pattern (not shown) for patterning the gate electrode GE is formed.

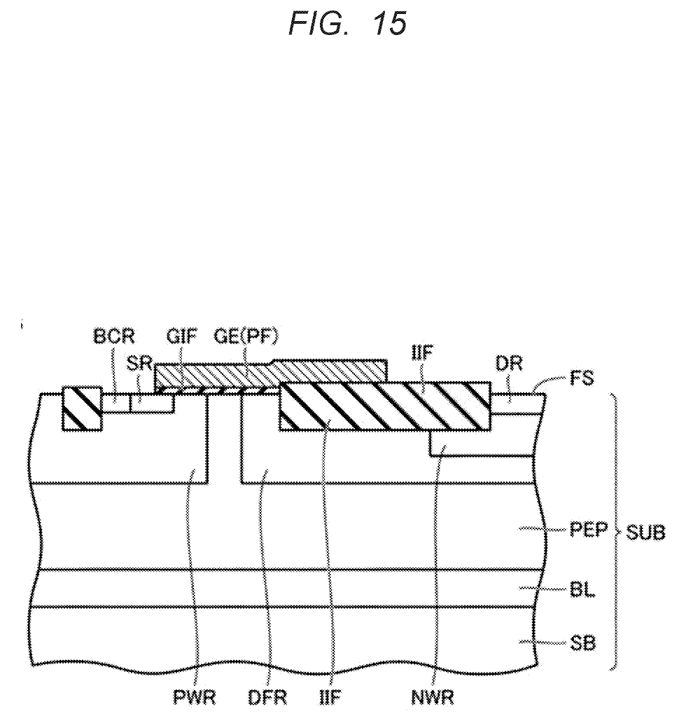

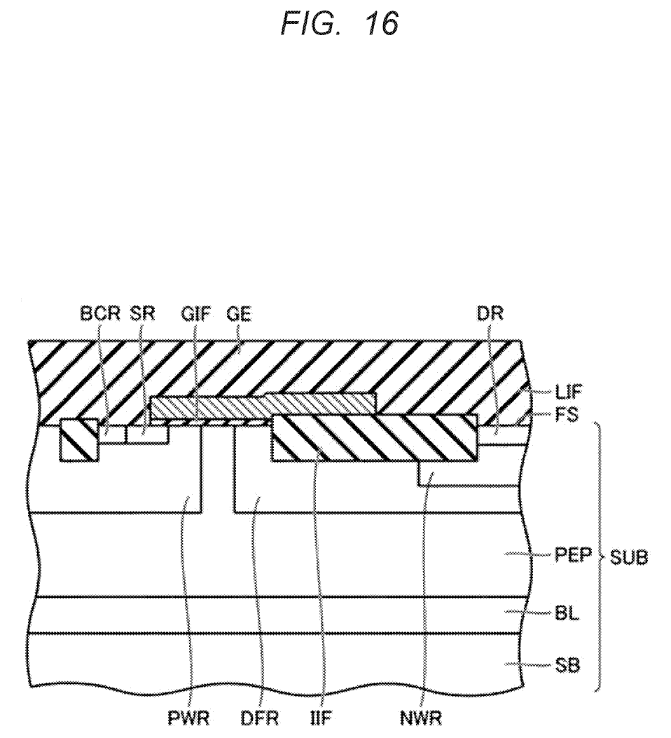

Next, using the photoresist pattern as an etching mask, etching is performed on the polysilicon film PF (first polysilicon film PF1 and second polysilicon film PF2). As a result, as shown in FIG. 15, the gate electrode GE is formed. Next, as shown in FIG. 16, for example, by chemical vapor deposition, an interlayer insulating film LIF is formed on the first main surface FS of the semiconductor substrate SUB so as to cover the gate electrode GE and others. Subsequently, by forming the contact plug CP, the isolation insulating film DIF, the source electrode SEL, and the drain electrode DEL, the semiconductor device SED shown in FIG. 1 is formed.

In the manufacturing method of the aforementioned semiconductor device SED, before forming the trench TCV, an implant species (phosphorus) that promotes oxidation is implanted into the portion of the semiconductor substrate SUB located in the isolation region ISR defined at the first main surface FS. This allows for the suppression of electrical short circuits between the gate electrode GE and the semiconductor substrate SUB (drift region DFR), even if needle-like residues RES occur in the trench TCV. This will be explained in comparison with the manufacturing method of a semiconductor device according to a comparative example.

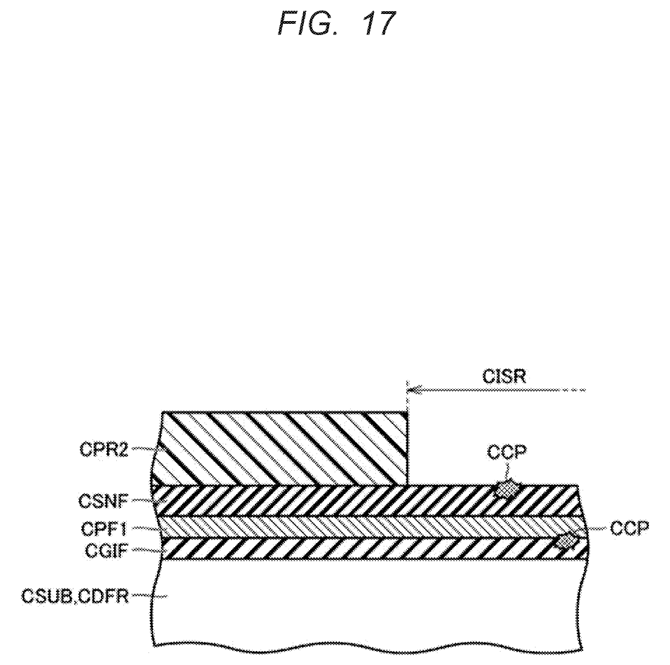

In the manufacturing method of the semiconductor device according to the comparative example, the gate electrode formation step and the isolation insulating film formation step are mainly described. First, as shown in FIG. 17, the gate insulating film CGIF, the first polysilicon film CPF1, and the silicon nitride film CSNF are formed to cover the semiconductor substrate CSUB (drift region CDFR). At this time, foreign matters CCP may occur in the gate insulating film CGIF or the first polysilicon film CPF1, etc. Next, by performing a predetermined photolithography process, the photoresist pattern CPR2 is formed. The photoresist pattern CPR2 is formed to expose the isolation region CISR.

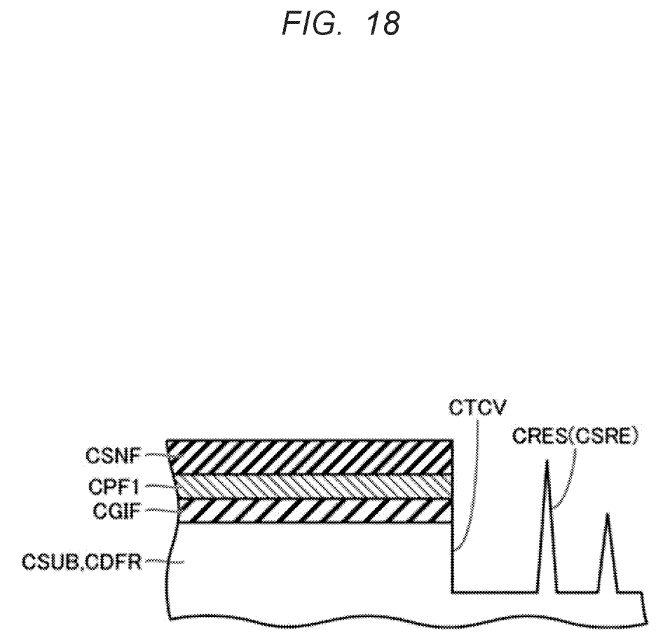

Next, using the photoresist pattern CPR2, etc., as an etching mask, anisotropic etching is performed on the upper surface of the exposed semiconductor substrate CSUB (isolation region CISR). As a result, the trench CTCV is formed as shown in FIG. 18. At this time, if foreign matter CCP (see FIG. 17) has occurred in the first polysilicon film CPF1 or the silicon nitride film CSNF, etc., that foreign matter CCP acts as a mask, and needle-like residues CRES may occur in the trench CTCV. The needle-like residues CRES include silicon CSRE located in the drift region CDFR.

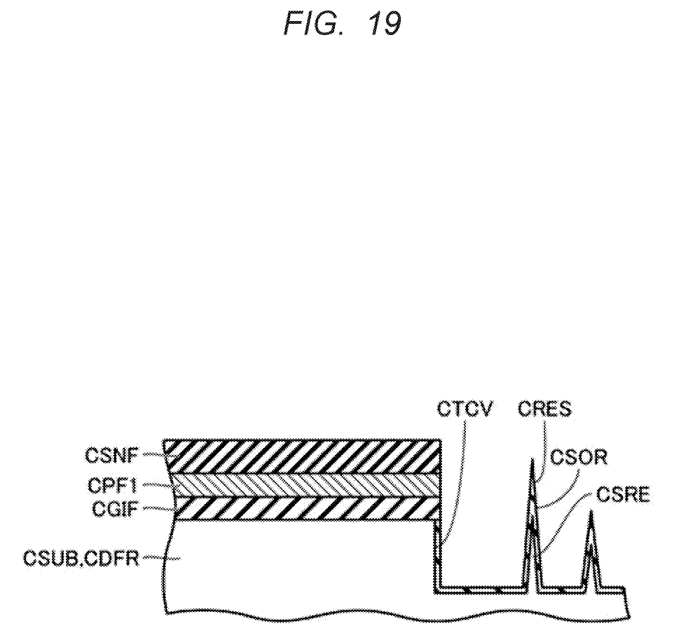

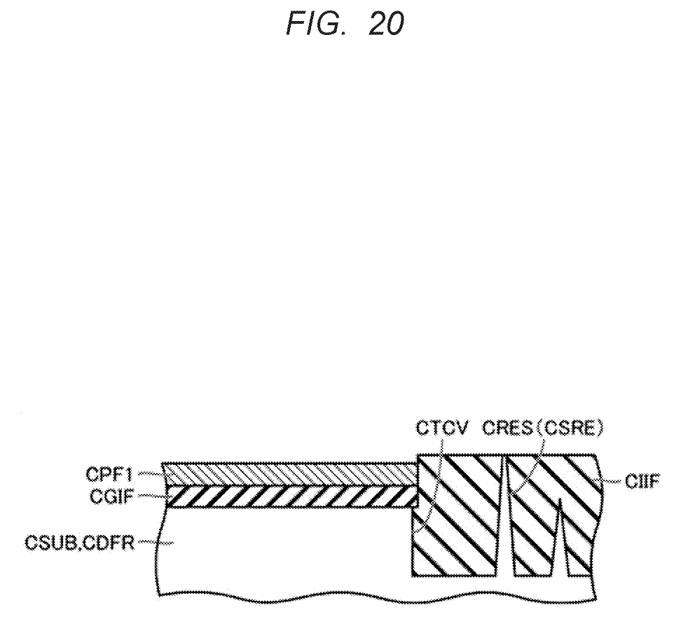

Next, as shown in FIG. 19, by performing a thermal oxidation process (liner oxidation), a silicon oxide film CSOR is formed on the bottom and sidewall surfaces of the exposed trench CTVC. If needle-like residues CRES have occurred, a silicon oxide film CSOR is formed on the surface of the needle-like residues CRES (silicon CSRE, etc.). Next, through a process similar to that shown in FIGS. 11-13 described above, an isolation insulating film CIIF is formed in the trench CTVC as shown in FIG. 20. At this time, it is assumed that the tip portion of the needle-like residues CRES may be exposed from the upper surface of the isolation insulating film CIIF.

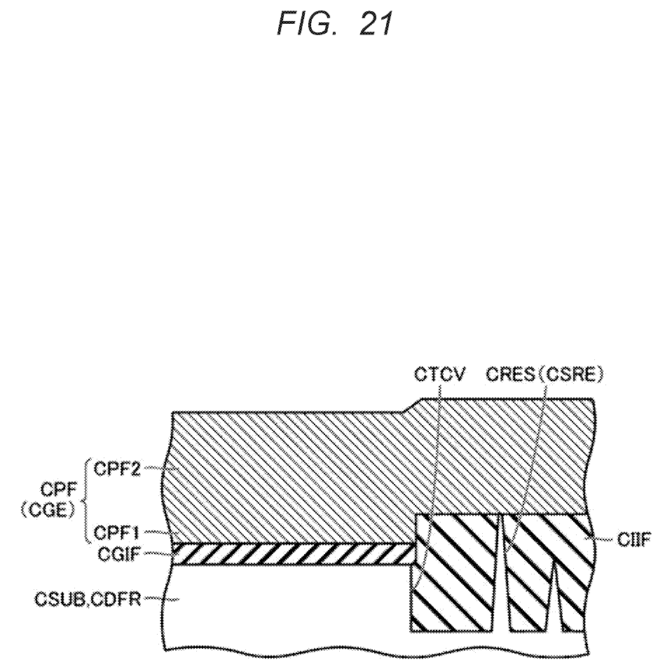

Next, as shown in FIG. 21, the second polysilicon film CPF2 is formed to contact the first polysilicon film CPF1. Next, by performing an etching process on the polysilicon film CPF (the first polysilicon film CPF1 and the second polysilicon film CPF2), the gate electrode CGE is formed. In the semiconductor device according to the comparative example, the isolation insulating film CIIF and the gate electrode CGE are formed through the above steps.

In the semiconductor device according to the comparative

example, it is assumed that needle-like residues CRES occur in the trench TCV due to foreign matter CCP, as shown in FIG. 18. In this case, as shown in FIG. 19, after forming the trench CTCV, the thermal oxidation process oxidizes the bottom and sidewall surfaces of the trench CTCV and the surface of the needle-like residues CRES, forming a silicon oxide film CSOR. Therefore, the position of the tip portion of the needle-like residues CRES (silicon CSRE (first polysilicon film CPF1)) after the thermal oxidation process is lower than the position of the tip portion of the needle-like residues CRES (silicon CSRE (first polysilicon film CPF1)) before the thermal oxidation process.

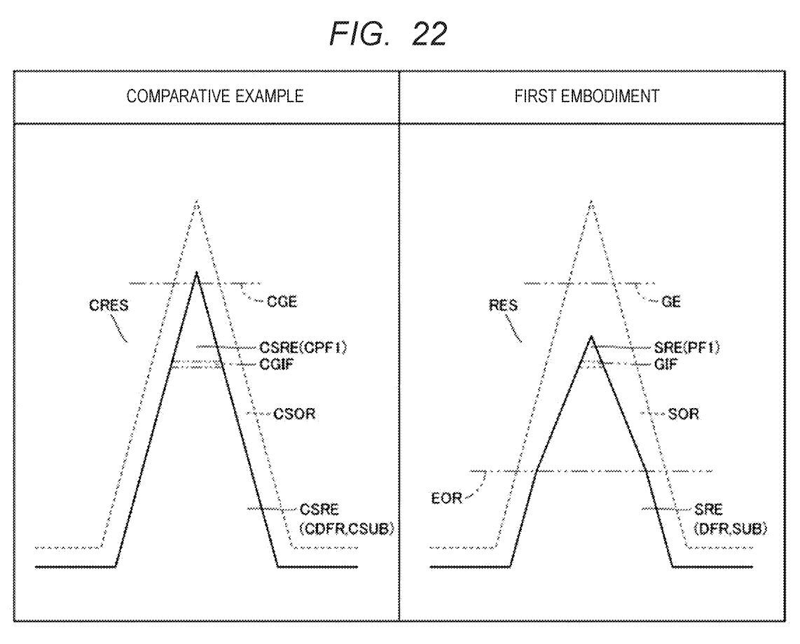

As shown in FIG. 20, it is assumed that, depending on the needle-like residues CRES, the tip portion of the needle-like residues CRES (silicon CSRE (first polysilicon film CPF1)) may be exposed from the upper surface of the isolation insulating film CIIF after the isolation insulating film CIIF is formed. In that case, as shown in the left column of FIG. 22, the gate electrode CGE contacts the needle-like residues CRES (first polysilicon film CPF1). In such a state, if the silicon oxide film (gate insulating film CGIF) undergoes dielectric breakdown, it is assumed that the gate electrode CGE and the drift region CDFR (semiconductor substrate CSUB) will electrically short-circuit with each other.

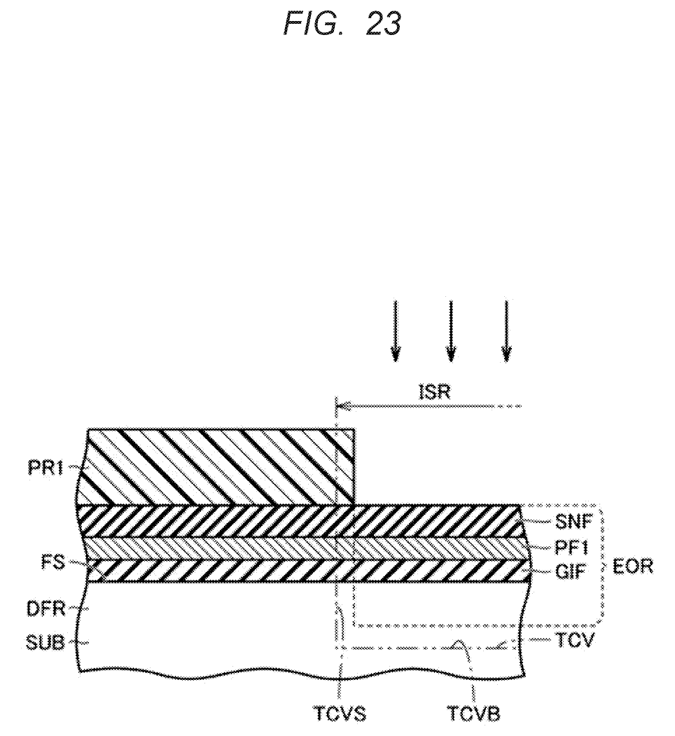

In contrast to the comparative example, in the semiconductor device according to the first embodiment, as shown in FIG. 23, before forming the trench TCV, an implant species that promotes oxidation is implanted into the portion of the semiconductor substrate SUB (implantation region EOR) located shallower than the position that becomes the bottom TCVB of the trench TCV and more inward than the position that becomes the sidewall surface TCVS of the trench TCV. This allows for the suppression of electrical short circuits between the gate electrode GE and the semiconductor substrate SUB (drift region DFR). Here, it is assumed that needle-like residues RES with the same height as needle-like residues CRES according to the comparative example occur in the trench TCV.

In that case, as shown in the right column of FIG. 22, by promoting the oxidation of the surface of the needle-like residues RES, the position of the tip portion of the needle-like residues RES (silicon SRE (first polysilicon film PF1)) after the thermal oxidation process becomes even lower than the position of the tip portion of the needle-like residues CRES (silicon CSRE (first polysilicon film CPF1)) after the thermal oxidation process according to the comparative example.

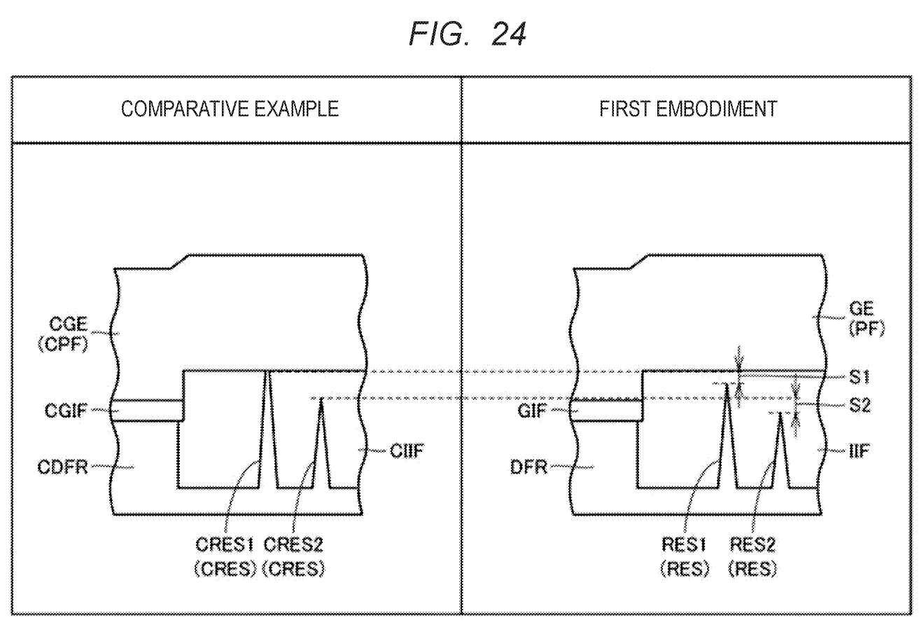

From another perspective, by performing a process that promotes oxidation (accelerated oxidation), the distance between the needle-like residues RES and the gate electrode GE can be increased. As shown in FIG. 24, the height of the first needle-like residues RES1 after implementing accelerated oxidation measures is lower by a distance corresponding to S1 than the height of the first needle-like residues CRES1 according to the comparative example without accelerated oxidation measures. Additionally, the height of the second needle-like residues RES2 after performing accelerated oxidation processing is lower by a distance corresponding to S2 than the height of the second needle-like residues CRES2 according to the comparative example without accelerated oxidation measures.

Thus, by securing a sufficient distance between the gate electrode GE and the needle-like residues RES (first polysilicon film PF1) through accelerated oxidation, the dielectric breakdown of the silicon oxide film (gate insulating film GIF) can be suppressed. As a result, the electrical short-circuiting between the gate electrode GE and the drift region DFR (semiconductor substrate SUB) can be suppressed.

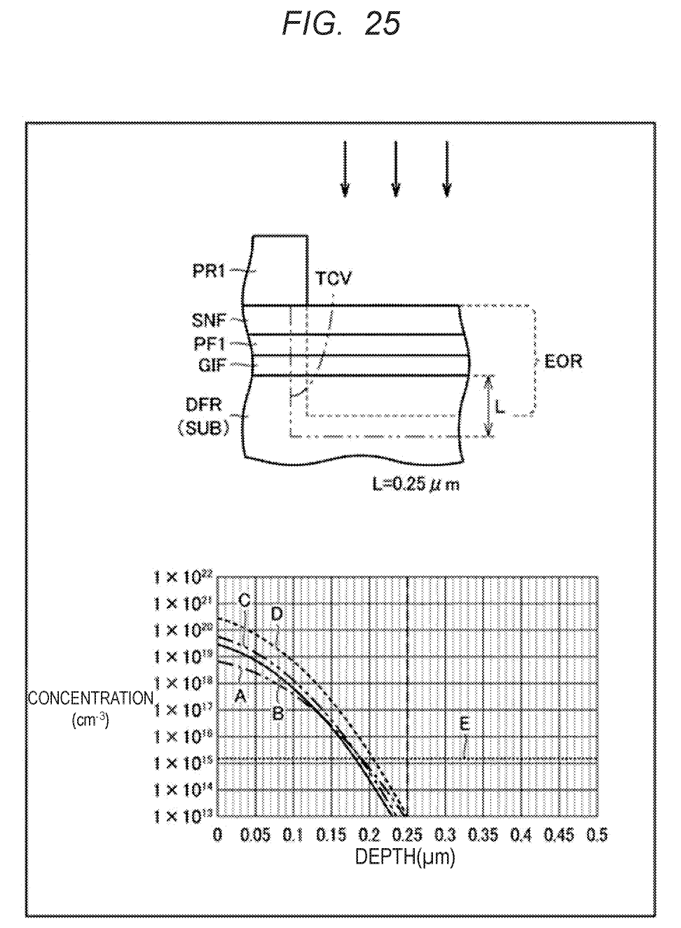

Next, the inventors conducted a simulation-based evaluation of the implantation conditions for the oxidation species to perform accelerated oxidation. The evaluation results will be explained. As shown in FIG. 25, phosphorus was set as the implant species for the oxidation species. It was set so that phosphorus would not be implanted into the semiconductor substrate beyond the bottom of the trench TCV (L=0.25μm). Additionally, it was set so that phosphorus would not be implanted into the semiconductor substrate beyond the sidewall surface of the trench TCV (implantation region EOR).

Four conditions, A, B, C, and D, were set as the implantation conditions for phosphorus. In condition A, the dose amount of phosphorus was set to 1×10¹⁴ cm⁻², and the implantation energy of phosphorus was set to 120 keV. In condition B, the dose amount of phosphorus was set to 5×10¹⁴ cm⁻², and the implantation energy of phosphorus was set to 110 keV. In condition C, the dose amount of phosphorus was set to 1.0×10¹⁵ cm⁻², and the implantation energy of phosphorus was set to 110 keV. In condition D, the dose amount of phosphorus was set to 5×10¹⁵ cm⁻², and the implantation energy of phosphorus was set to 110 keV.

As the criterion for determining the implantation conditions, the concentration of phosphorus at a depth (L=0.25μm) from the upper surface of the semiconductor substrate SUB (drift region DFR) was set to 1.5×10¹³ cm⁻³. This phosphorus concentration corresponds to 1/100 of the boron concentration E (1.5×10¹⁵ cm⁻³) in the epitaxial region PEP. Considering the results of the simulation-based evaluation and the criteria, the inventors set the implantation energy of phosphorus to be 100 keV or more and 110 keV or less. Additionally, the dose amount of phosphorus was set to be 1.0×10¹⁵ cm⁻² or more and 5×10¹⁵ cm⁻² or less.

Furthermore, the inventors separately evaluated the oxide film thickness when phosphorus was implanted under these implantation conditions and thermal oxidation process was performed. As a result, it was confirmed that the oxide film thickness increased to 16 nm due to the promotion of oxidation by phosphorus implantation, compared to 10 nm when phosphorus was not implanted.

In the above-described embodiment, phosphorus was mentioned as the implant species for performing accelerated oxidation. The implant species for performing accelerated oxidation is not limited to phosphorus; for example, n-type impurities such as arsenic can be applied as the implant species.

### Second Embodiment

In the manufacturing method of the semiconductor device according to the first embodiment, the case where an implant species for performing accelerated oxidation is implanted before forming the trench TCV was described. Here, an example of a manufacturing method in which an implant species for performing accelerated oxidation is implanted after forming the trench TCV will be described.

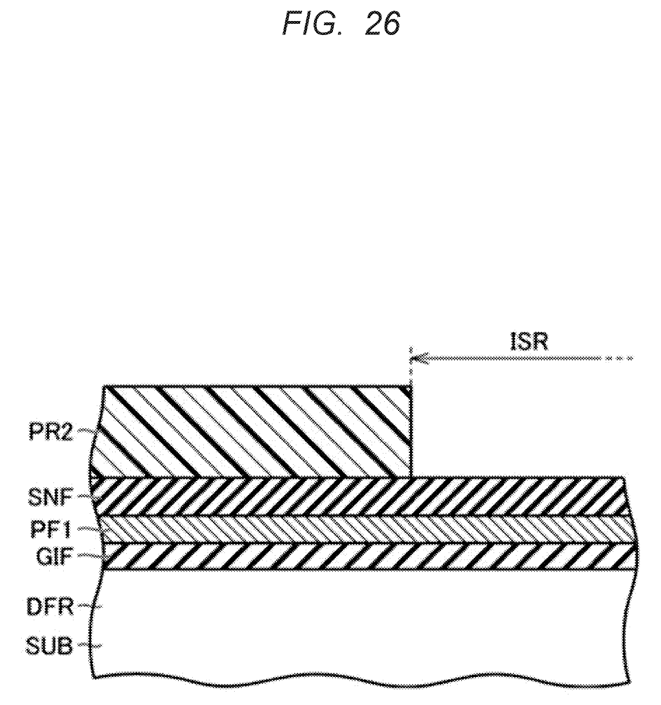

First, after going through the same steps as those shown in FIGS. 2-5 described above, as shown in FIG. 26, by performing a predetermined photolithography process, the photoresist pattern PR2 is formed to contact the upper surface of the silicon nitride film SNF. The photoresist pattern PR2 is formed to expose the silicon nitride film SNF located in the isolation region ISR.

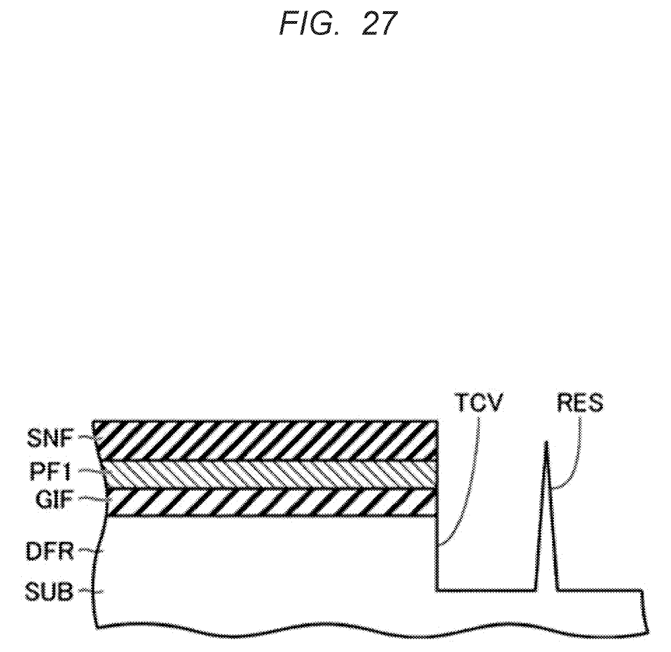

Next, using the photoresist pattern PR2, etc., as an etching mask, anisotropic etching is performed on the silicon nitride film SNF, etc., and the semiconductor substrate SUB. As a result, as shown in FIG. 27, a trench TCV is formed in the semiconductor substrate SUB (isolation region ISR). At this time, if foreign matter has occurred in the first polysilicon film PF1 or the silicon nitride film SNF, etc., the foreign matter may act as a mask, causing needle-like residues RES to occur in the trench TCV.

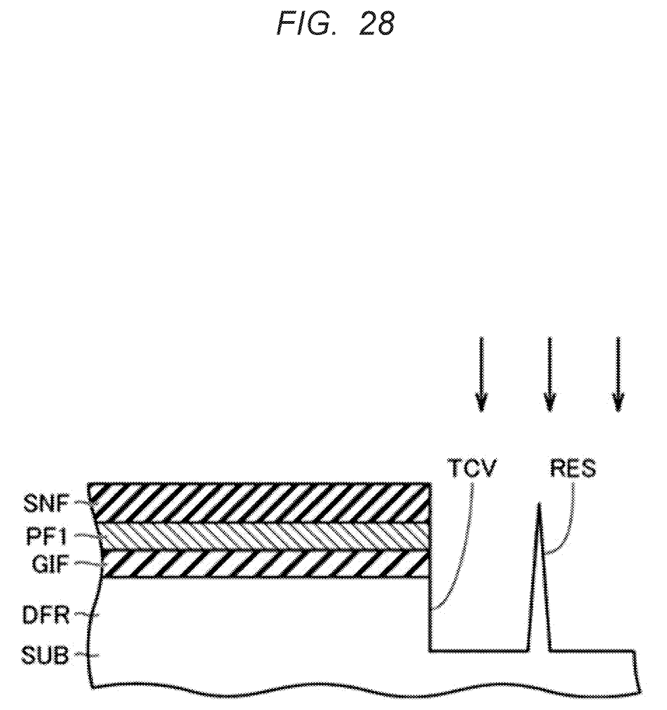

Next, as shown in FIG. 28, silicon is implanted into the trench TCV as an implant species to promote oxidation in the trench TCV. The implantation energy of silicon is, for example, 90 keV or more and 100 keV or less. Also, the dose amount of silicon is, for example, 1.0×10¹⁵ cm⁻² or more and 1.5×10¹⁵ cm⁻² or less. The conditions for silicon implantation will be described later.

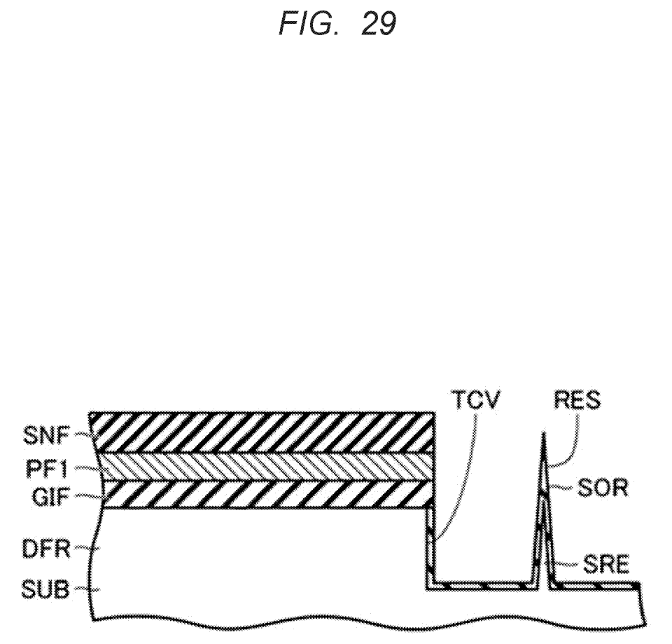

Next, as shown in FIG. 29, by performing thermal oxidation process, a silicon oxide film SOR is formed on the bottom surface and the sidewall surface of the exposed trench TCV. If needle-like residues RES are present, a silicon oxide film SOR is formed on the surface of the needle-like residues RES (silicon SRE, etc.).

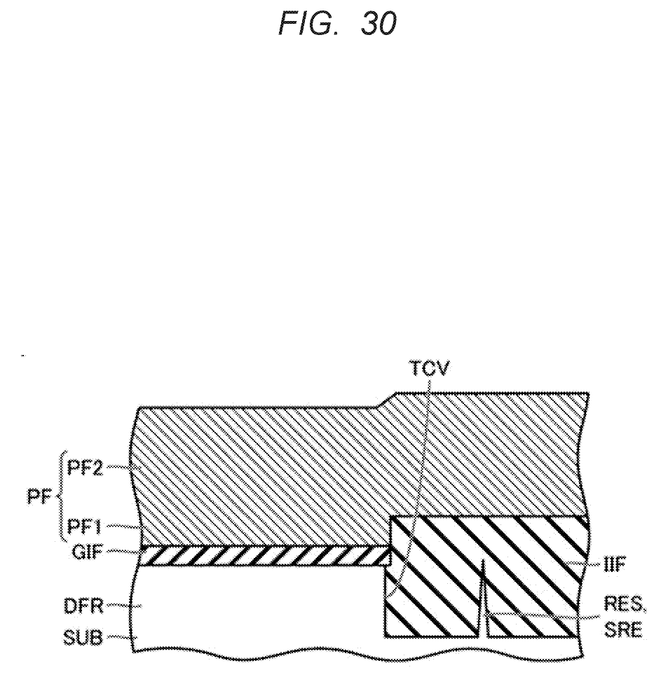

Next, through steps similar to those shown in FIGS. 11-14, as shown in FIG. 30, a second polysilicon film PF2 is formed in contact with the first polysilicon film PF1. Subsequently, through processes similar to those shown in FIGS. 15 and 16, a semiconductor device SED (see FIG. 1) is formed.

In the manufacturing method of the semiconductor device SED according to the second embodiment, after the trench TCV is formed, an implant species (silicon) that promotes oxidation is implanted into the trench TCV. Due to silicon implantation, damage from the implantation occurs on the bottom surface TCVB and sidewall surface TCVS of the trench TCV and on the surface of the needle-like residues RES. When performing thermal oxidation process (liner oxidation), oxidizing species penetrate from the damaged areas, and particularly in the needle-like residues RES, the oxidation of the surface of the needle-like residues RES is promoted.

As a result, similar to the case where phosphorus is implanted, the distance between the needle-like residues RES and the gate electrode GE is increased. As a result, it is possible to suppress the occurrence of electrical short-circuiting between the gate electrode GE and the semiconductor substrate SUB (drift region DFR). Furthermore, by implanting silicon that does not exhibit p-type and n-type conductivity as the implant species, it is possible to suppress the influence on electrical characteristics in the semiconductor device SED.

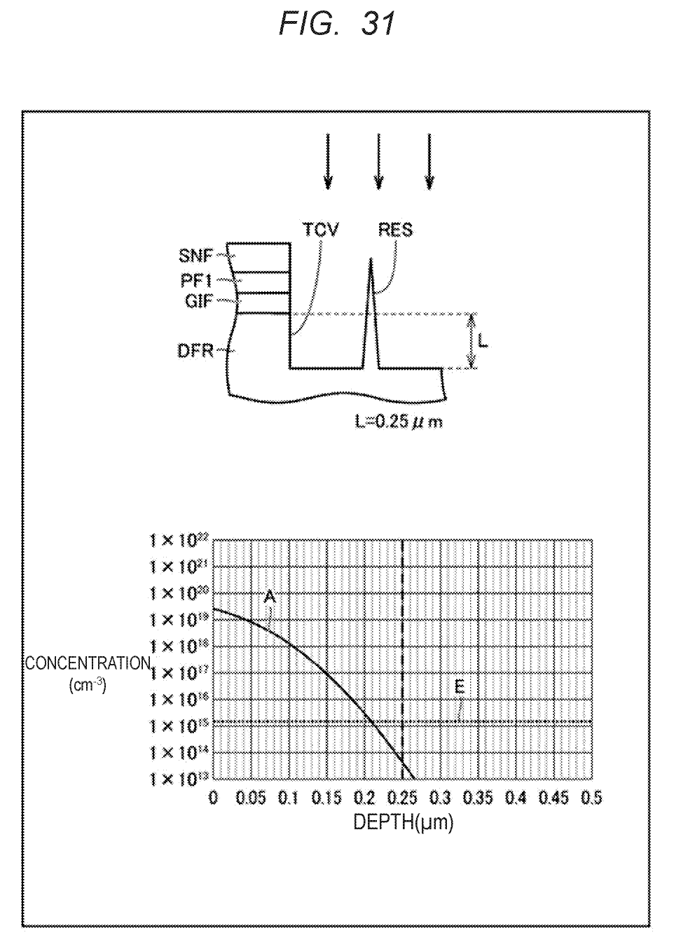

Next, the inventors conducted an evaluation by simulation regarding the implantation conditions of oxidizing species for performing accelerated oxidation. The evaluation results will be described. As shown in FIG. 31, as the silicon implantation conditions, the silicon dose amount was set to 5×10¹⁴ cm⁻², and the silicon implantation energy was set to 100 keV (Condition A). An evaluation by simulation was conducted under this Condition A.

The inventors, considering the evaluation results from the simulation and a concentration equivalent to 1/100 of the boron concentration E (1.5×10¹⁵ cm⁻³) of the epitaxial region PEP, set the silicon implantation energy to 90 keV or more and 100 keV or less. Also, the silicon dose amount was set to 1.0×10¹⁵ cm⁻² or more and 1.5×10¹⁵ cm⁻² or less.

In the above-described embodiments, the semiconductor device SED equipped with an LDMOS transistor LDMT was described using the example of a gate electrode GE extending from the first main surface FS of the semiconductor substrate SUB onto the isolation insulating film IIL.

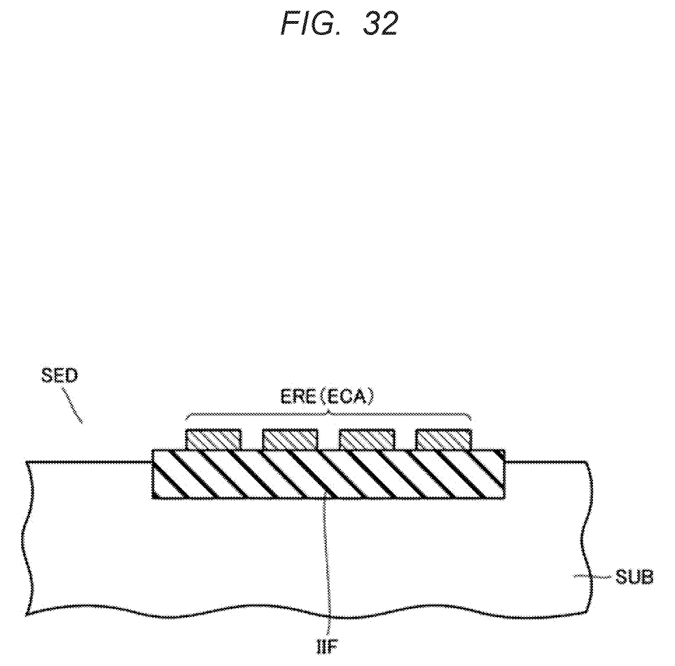

As shown in FIG. 32, the semiconductor device SED may be a semiconductor device SED equipped with a resistor element ERE formed in contact with the isolation insulating film IIF. Additionally, the semiconductor device SED may be equipped with a capacitor element ECA having a desired capacitance formed in contact with the isolation insulating film IIF.

Even in such a semiconductor device SED, by applying the manufacturing method described in the above embodiments, it is possible to suppress electrical short-circuiting between the semiconductor substrate SUB and the resistor element ERE. Furthermore, it is possible to suppress electrical short- circuiting between the semiconductor substrate SUB and the capacitor element ECA.

Finally, the shape of the needle-like residues RES after accelerated oxidation will be described. In the needle-like residues RES before performing thermal oxidation process (liner oxidation), there are portions where phosphorus, etc., has been implanted and portions where it has not been implanted. Phosphorus, etc., is implanted into the upper part of the needle-like residues RES, while the lower part of the needle-like residues RES is not implanted with phosphorus, etc. As a result, by thermal oxidation process (liner oxidation), the lower part of the needle-like residues RES is normally oxidized, while the upper part of the needle-like residues RES undergoes accelerated oxidation.

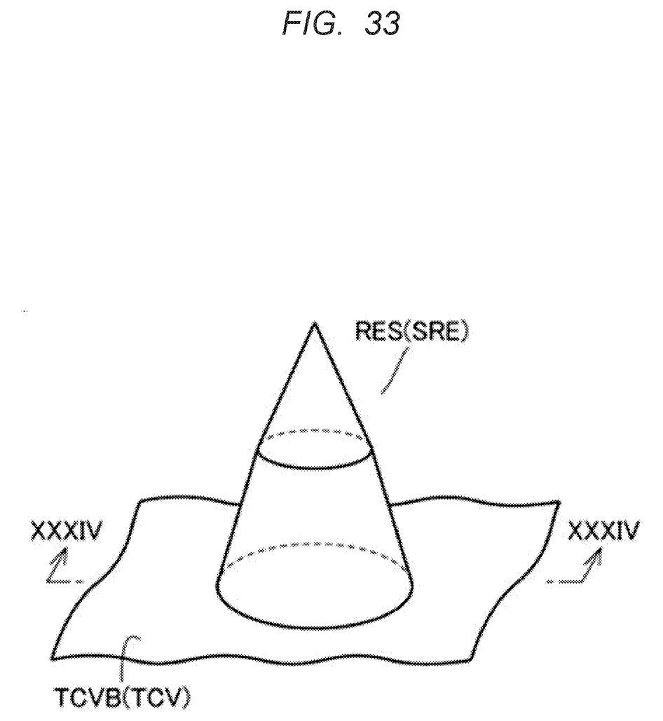

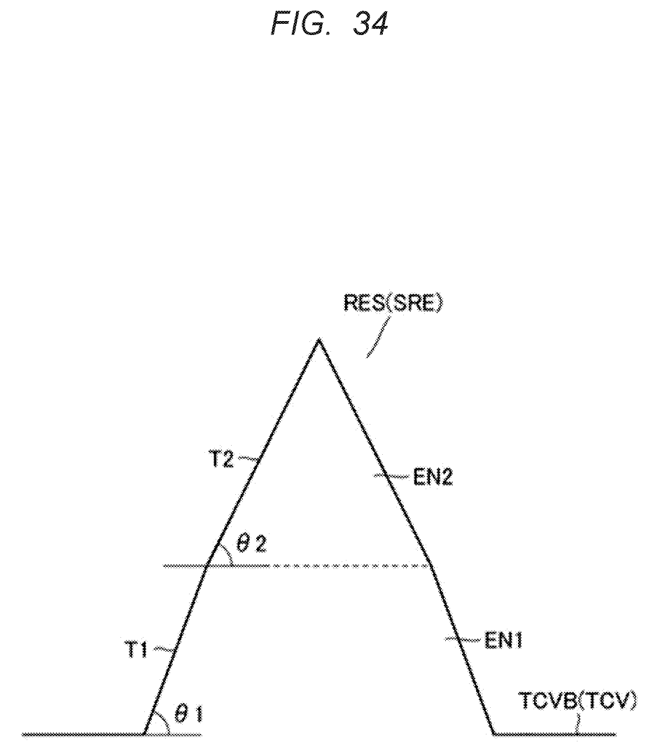

Therefore, as shown in FIGS. 33 and 34, the needle-like residues RES remaining as silicon SRE are considered to have a shape combining a truncated cone EN1 and a cone EN2. It should be noted that the truncated cone EN1 and the cone EN2 are not intended to represent geometrically precise shapes. The truncated cone EN1 has a generatrix T1, and the angle formed between the generatrix T1 and the bottom surface TCVB of the trench TCV is angle θ1. The cone EN2 has a generatrix T2, and the angle formed between the generatrix T2 and the bottom surface TCVB of the trench TCV is angle θ2. The angle θ2 is smaller than the angle θ1.

It should be noted that the semiconductor devices and their manufacturing methods described in each embodiment can be variously combined as necessary.

Although the invention made by the present inventor has been specifically described based on the embodiment, the present invention is not limited to the as described above embodiment, and it is needless to say that various modifications can be made without departing from the gist thereof.

What is claimed is:

1. A method of manufacturing a semiconductor device, the method comprising:
preparing a semiconductor substrate having a first main surface;
forming a first polysilicon film on the first main surface via a first insulating film;
forming a first mask material on the first polysilicon film;
performing a first etching process on the first polysilicon film, on the first insulating film, and on the semiconductor substrate using the first mask material as an etching mask to form an isolation trench in a part of the semiconductor substrate;
performing an oxidation process in the isolation trench;
forming an isolation insulating film in the isolation trench;
forming a second polysilicon film on an upper surface of the first polysilicon film and on an upper surface of the isolation insulating film; and
performing a second etching process on the second polysilicon film and on the first polysilicon film to form a polysilicon pattern extending from the first main surface onto the isolation insulating film,
wherein, before performing the oxidation process in the isolation trench, an implant species is implanted into the part of the semiconductor substrate by ion implantation.

2. The method according to claim 1,
wherein implanting the implant species into the part of the semiconductor substrate is performed before forming the isolation trench.

3. The method according to claim 2,
wherein implanting the implant species into the part of the semiconductor substrate comprises:
after forming the first mask material, forming a second mask material on the first mask material; and
implanting the implant species into the part of the semiconductor substrate using the second mask material as an implantation mask.

4. The method according to claim 3,
wherein, in forming the second mask material, the second mask material is formed in such a manner that a part of the second mask material overlaps a region where the isolation trench is formed, wherein, in implanting the implant species, the implant species is implanted using the second mask material as an implantation mask, and
wherein, in forming the isolation trench, the isolation trench is formed deeper than an implantation region containing the implant species formed in the semiconductor substrate.

5. The method according to claim 2,
wherein the implant species includes an impurity of a first conductivity type.

6. The method according to claim 5,
wherein the implant species includes either arsenic or phosphorus.

7. The method according to claim 1,
wherein implanting the implant species into the part of the semiconductor substrate is performed after forming the isolation trench.

8. The method according to claim 7,
wherein the implant species includes silicon.

9. The method according to claim 1, comprising:
forming a gate electrode; and
after forming the gate electrode, forming a source region and a drain region,
wherein the gate electrode is formed of the polysilicon pattern,
wherein the source region and the drain region are formed in the semiconductor substrate and at the first main surface, and
wherein the isolation insulating film is disposed between the source region and the drain region.

10. The method according to claim 1,
wherein forming the polysilicon pattern includes forming a resistor element.

11. The method according to claim 1,
wherein forming the polysilicon pattern includes forming a capacitor element.

12. The method according to claim 1, comprising:
forming a drift region in the semiconductor substrate,
wherein implanting the implant species is performed after forming the drift region, and
wherein the isolation trench is formed in the drift region.

13. The method according to claim 1,
wherein the implant species has a function of promoting oxidation in the isolation trench during the oxidation process.
